(19) United States
(12) Patent Application Publication
(10) Pub. No.: US 2005/0062539 A1
(43) Pub. Date: Mar. 24, 2005

(54) Method and apparatus for current amplification

(76) Inventor: Chunyan Wang, Montreal (CA)

Correspondence Address: OGILVY RENAULT, 1981 MCGILL COLLEGE AVENUE, SUITE 1600, MONTREAL, QC, H3A2Y3, CA

(21) Appl. No.: 10/667,897

(22) Filed: Sep. 23, 2003

(51) Int. Cl. H03F 3/04

(52) U.S. Cl. 330/288

(57) ABSTRACT

There is described a method and circuit for amplifying an input current signal to provide an output current signal according to a predetermined gain profile. The method and circuit can be used for designing current-mode circuits employing MOS transistors or other kinds of electronic device that have three or more terminals. The circuit can operate with sub-nA currents, provide a very high current gain, and dissipate very low power. The structure of the circuit is simple and the transistors used do not have to have a large geometrical size. The capacitive loads are minimized and the operation speed is thus maximized with the minimum power dissipation.

### FIELD OF THE INVENTION

The invention relates to current amplifiers and current-mode circuits employing MOS transistors or other kinds of electronic devices that have three or more terminals.

### BACKGROUND OF THE INVENTION

In the design of an electronic system, the signal of interest, whether at the system input, at an intermediate stage, or at the output, may be too weak to drive succeeding stages. In this case, an amplifier is used to amplify the signal to a level that is more acceptable for the circuit. In the case of current amplification, many circuits exist in the state of the art.

A current amplifier can be implemented by using a current mirror with unequal MOS transistor aspect ratios, such as that shown in U.S. Pat. No. 5,834,951. However in this case, the current gain is limited by the practical geometrical sizes of the transistors.

Some current amplifiers composed of transimpedance and transconductance amplifiers may provide a high gain, but many of them have complex structures and few operate with sub nano-ampere currents. The present applicant proposed an amplifier with a simple structure capable of working with sub-nA currents in U.S. Pat. No. 6,583,670, but it needs two bias currents of micro-amperes to support its two stages.

Certain high-gain current amplifiers may be made by biasing the base voltages of MOS transistors operating in the weak inversion region, but making the base voltages different from the supply voltages may lead to a constraint of circuit implementation in standard N-well (or P-well) technology processes and it can cause significant leakage currents due to positively biased parasitic diodes. Instead of base biasing, some propose to bias the gates and to drive the sources of MOSFETs for current amplification and in this case, the transistors determining the amplification gain are made to operate in the weak inversion mode in order to have a high current gain. However, if the gain is really high, the amplified current may be too strong to drive the transistor in the weak inversion mode.

Therefore, there is a need for a new circuit operating in a nA range for high-gain current amplification with very low power dissipation and a simple structure.

### SUMMARY OF THE INVENTION

Accordingly, an object of the present invention is to overcome the drawbacks of the prior art.

According to a first broad aspect of the present invention, there is provided a method for amplifying an input current signal to provide an output current signal according to a predetermined gain profile, the method comprising: providing a first and a second semiconductor device each having at least a control terminal and two current terminals for a current to flow therethrough, wherein the input current signal is fed through the two current terminals of the first semiconductor device and the output current signal passes through the two current terminals of the second semiconductor device; controlling a second voltage level of a control terminal of the second semiconductor device such that the second voltage level follows a first voltage level of a control terminal of the first semiconductor device; providing circuitry responsive to the input current signal to provide the first voltage level such that the first voltage level varies with the input current signal to cause the second semiconductor device to generate the output current signal according to the predetermined gain profile, wherein the circuitry biases the first semiconductor device in a first operating region, and wherein the second semiconductor device is biased in a second operating region having a higher device-current to control-voltage ratio than the first operating region.

Preferably, providing circuitry comprises providing a third semiconductor device having at least a control terminal and two current terminals, connected to the first device in such a way that the control terminal of the 3^{rd} device can adjust the bias voltage, i.e. the voltage across the two current terminals of the first device, while the signal at the node of the control terminal of the first device still varies according to the input current. This can be done by connecting the two devices in series, with one of the two current terminals of the third semiconductor device shorted to the control terminal of the first semiconductor device; and applying a control signal to the control terminal of the third semiconductor device to set a voltage across the first semiconductor device.

Also preferably, the predetermined gain profile is adaptive, and providing circuitry comprises providing a feedback system which causes the voltage across the current terminals of the first semiconductor device to vary as a function of the input current signal such that a decrease of the input current will produce a sufficient change in the voltage to result in an increase in the current gain.

According to a second broad aspect of the present invention, there is provided a circuit for amplifying an input current signal to provide an output current signal according to a predetermined gain profile, the circuit comprising: a first semiconductor device having at least a control terminal, and two current terminals for a current to flow therethrough, wherein the input current signal is fed through the two current terminals of the first semiconductor device; a second semiconductor device having at least a control terminal and two current terminals for a current to flow therethrough, wherein a second voltage level of the control terminal of the second semiconductor device follows a first voltage level of the control terminal of the first semiconductor device, and wherein the output current signal passes through the two current terminals of the second semiconductor device; and circuitry responsive to the input current signal to provide the first voltage level such that the first voltage level varies with the input current signal to cause the second semiconductor device to generate the output current signal according to the predetermined gain profile, wherein the circuitry biases the first semiconductor device in a first operating region, and wherein the second semiconductor device is biased in a second operating region having a higher device-current to control-voltage ratio than the first operating region.

Preferably, the circuitry comprises a third semiconductor device having at least a control terminal and two current terminals for a current to flow therethrough, in series with the first semiconductor device such that the input current signal is fed through the two current terminals of the third semiconductor device, and wherein the input current terminal of the third semiconductor device is connected to the control terminal of the first semiconductor device, whereby applying a control signal to the control terminal of the third semiconductor device sets a voltage across the first semiconductor device.

Also preferably, the predetermined gain profile is adaptive, and the circuitry comprises a feedback system which causes the voltage across the current terminals of the first semiconductor device to vary as a function of the input current signal such that a decrease of the input current will produce a sufficient change in the voltage to result in an increase in the current gain.

### BRIEF DESCRIPTION OF THE DRAWINGS

These and other features, aspects and advantages of the present invention will become better understood with regard to the following description and accompanying drawings wherein:

FIG. 1 is a circuit of two MOS transistors having the gate-to-source voltage Vgs′ of the second transistor depending on that of the first one, but their drain-to-source voltages can be different and not depend on each other;

FIG. 2 is a curve of i_{DS} versus v_{DS} of the MOS transistors in FIG. 1 in the case that they are identical;

FIG. 3 is a circuit structure for current operation with two devices represented by ellipses;

FIG. 4 is a current amplifier with f=1, i.e. the transistor N1 and N2 have a common gate-to-source voltage and the gain control terminal is Vgc;

FIG. 5 is a DC sweep response of the circuit shown in FIG. 4;

FIG. 6 is a transient response of the circuit shown in FIG. 4 when the frequency of the input current is 100 kHz;

FIG. 7 is a transient response of the circuit shown in FIG. 4 when the input current is a pulse signal;

FIG. 8 is a circuit of a current amplifier with its gain adapting to the input signal magnitude;

FIG. 9 is a graph of the current gain versus the input current of the circuit shown in FIG. 8;

FIG. 10 is a flowchart of the method according to the invention.

### DETAILED DESCRIPTION OF THE PREFERRED EMBODIMENT

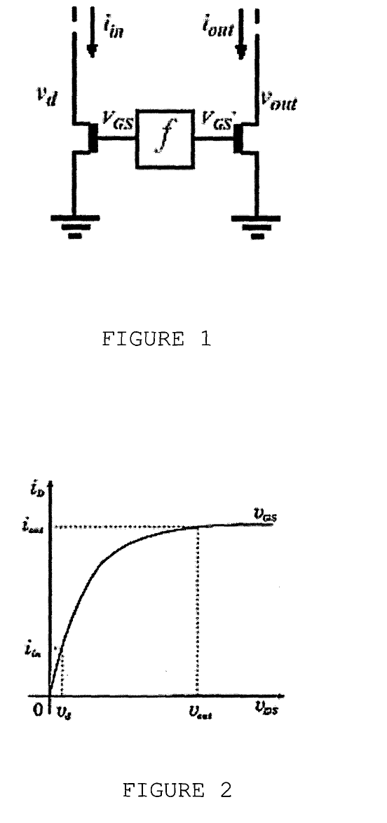

If two almost identical transistors, as those shown in FIG. 1, have the same gate-to-source voltage, but one has a small drain-to-source voltage and operates in the triode mode, while the other has a larger drain-to-source voltage and operates in the saturation mode, the current of the latter will definitely be stronger than that in the former. In FIG. 1, the transistor receiving the input current iᵢₙ is in the triode mode and the other in the saturation mode. The difference between iₒᵤₜ and iᵢₙ is shown in FIG. 2. The characteristic of i_{D} versus v_{DS} of the MOS transistors is shown. With the same gate-to-source voltage, the current in the saturation mode is greater than that in the triode mode.

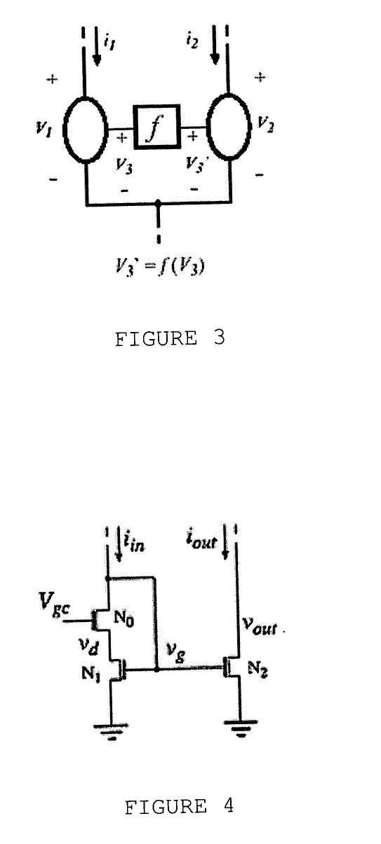

If any semiconductor device of three or more terminals having characteristics similar to those of MOS transistors are connected as shown in FIG. 3 to have a common voltage V₃ across two terminals, and the voltages V₁ and V₂ are made different, the currents i₁ and i₂ can be very different. The devices may operate in different modes. Controlling the common voltage V₃ by the weaker current that is the input signal, the stronger current will be the output signal varying with the input signal. If i₂>>i₁ and V₃ varies according to i₁, i₂ can be considered as an amplified current. V₃′ varies as a function of V₃. The two devices in FIG. 3 are represented by ellipses. The devices can be MOSFETs, BJTs, or any other electronic devices with at least three terminals.

The function box ƒ illustrated in FIGS. 1 and 3 represents any linear or non-linear function which would cause V_{GS}′ to follow V_{GS}. For example, V_{GS}′=kV_{GS}+b, where k and b are constant is an example of a linear function. The case of k=1 and b=0 is used for the preferred embodiment of the invention, shown in FIG. 4, where there is a direct connection between the two gates of the two transistors. If k=1 and b≠0, the amplification of the circuit can be modulated by providing an additional component in the output current.

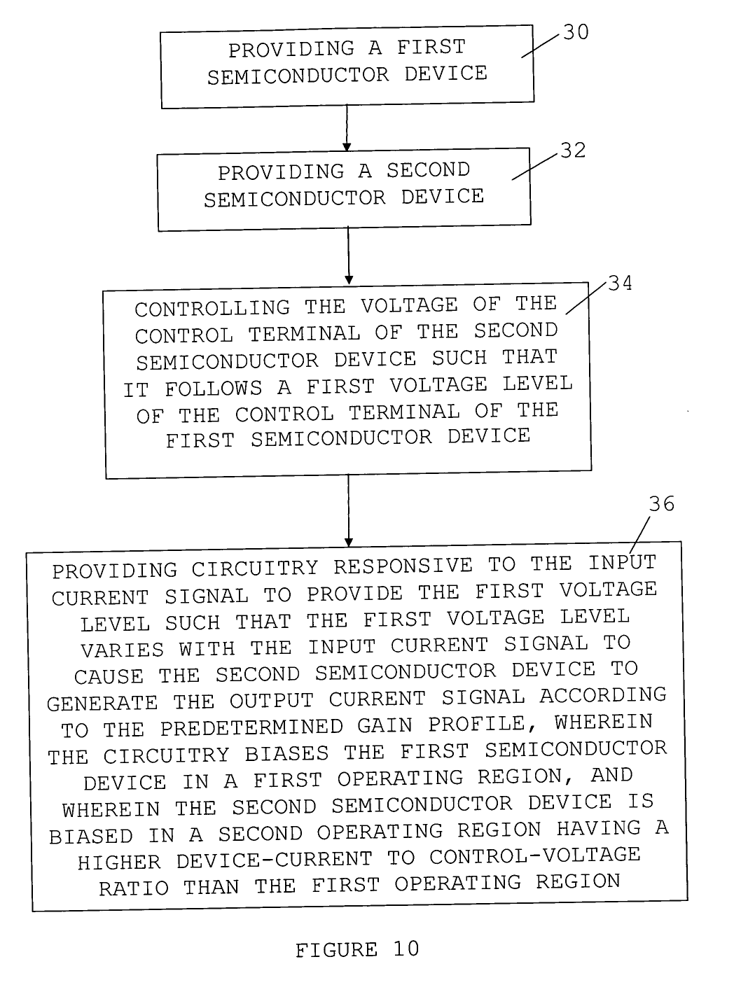

Therefore, the method according to the invention, illustrated in FIG. 10, consists in providing a first semiconductor device 30 and a second semiconductor device 32 and controlling the voltage of the control terminal of the second semiconductor device such that it follows the voltage of the control terminal of the first semiconductor device 34. This can be done by providing a direct connection between the two control terminals of the semiconductor devices. Circuitry is then provided which is responsive to the input current signal in order to generate an output current signal according to a predetermined gain profile. The voltage at the common terminal depends on the input current. The circuitry also biases the first semiconductor device in a first operating region, and the second semiconductor device is biased in a second operating region having a higher device-current to control-voltage ratio than the first operating region 36.

In FIG. 4, a basic structure of a current amplifier designed with the principle set out above is illustrated. The control signal V_{gc} is applied to adjust v_{d} so that the transistor N₁ is driven in the triode mode. Transistor N₂ is driven in saturation mode. If the voltage V_{gc} is lowered, v_{d} will be reduced and v_{g} will be raised, increasing iₒᵤₜ. The ratio iₒᵤₜ/iᵢₙ can be expressed as:

$$\frac{{i}_{out}}{{i}_{in}} \approx \frac{\frac{β}{2} {( {v}_{g} - {V}_{t} )}^{2}}{β ( {v}_{g} - {V}_{t} ) {v}_{d}} = \frac{{v}_{g} - {V}_{t}}{2 {v}_{d}}$$

where β=μₙCₒₓW/L is the MOS transistor gain factor, assuming that N₁ and N₂ are identical, and Vₜ is the threshold voltage of the transistors. If 2v_{d}<<v_{g}−Vₜ, then iₒᵤₜ/iᵢₙ>>1. Thus, this very simple circuit can provide a very high current gain. The desired gain profile is determined by the characteristics of the two devices, N₁ and N₂ in this example, and the gain control, V_{gc} in this case, which are related to setting v_{g} and v_{d} in the circuit.

The common gate voltage v_{g} varies with the input current. For a given V_{gc}, the range of v_{g} is Vₜ+v_{d}<v_{g}<V_{DD}. The lower limit corresponds to the edge of the triode region of the transistor N₁. If this transistor is driven in the saturation region, the circuit behaves like a current mirror, providing no significant current gain. If v_{g} rises approaching the level of the supply voltage, the circuit will not be able to receive the input current correctly. If the input current varies, v_{g} will vary at the rate expressed as follows:

$$\frac{\partial {v}_{g}}{\partial {i}_{in}} = \frac{1}{β {v}_{d}} .$$

The two equations above show that the voltage v_{d} is an important parameter for the circuit operation. Decreasing v_{d} results in an increase of the current gain, but, as Δv_{g}/Δiᵢₙ is also increased, with the limitation of Vₜ+v_{d}<v_{g}<V_{DD}, the range of the input current variation is narrowed.

It should be noted that, in the circuit shown in FIG. 4, the voltage v_{d} depends on the control voltage V_{gc}, the current iᵢₙ, and (W/L)₀, the aspect ration of N₀. If V_{gc} and iᵢₙ are given, a smaller (W/L)₀ will result in a lower v_{d}, which leads to a higher gain and narrower range of the input current. Therefore, to have a wide input current range, (W/L)₀ should not be too small. However, a small (W/L)₀ will be suitable if the circuit is used for current comparison and triggering.

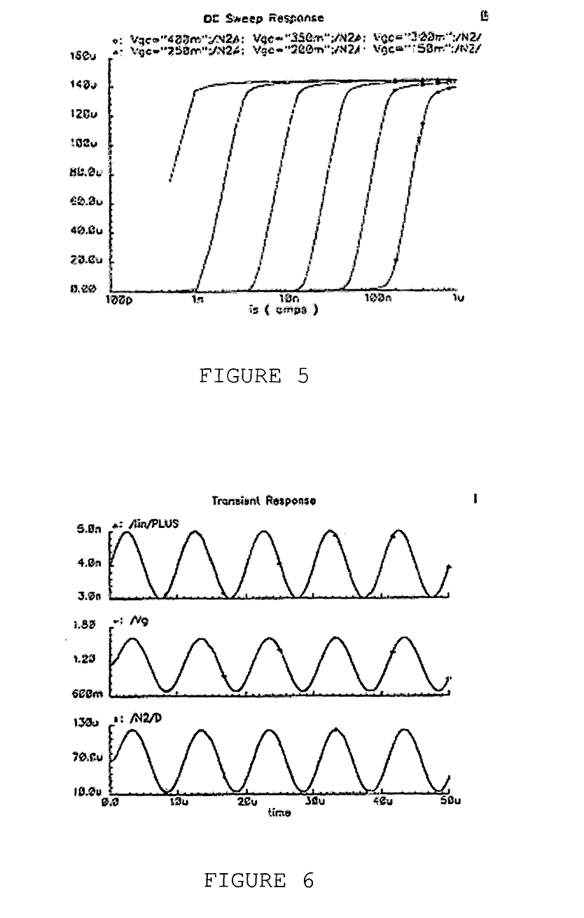

The circuit has been simulated using the transistor models of a 0.18 μm CMOS technology. The characteristics of the output current versus the input current are illustrated in FIG. 5. It shows that the circuit can provide a very high current gain under the conditions that the voltage v_{d}, set by means of V_{gc}, suits the range of the input current. For example, when the input current varies between 5 nA and 12 nA, and V_{gc} is 250 mV, the output current varies between 16 μA and 136 μA, responding almost linearly to the logarithmically compressed input current. The gain is about 70 to 80 dB. However, if V_{gc} is 50 mV higher or lower than 250 mV, the output current will be very low or very high, and it will not be able to reflect the input variation. Hence, for an input current varying in a certain range, the voltage v_{d} needs to be set to an appropriate level.

FIG. 5 is a graph of the characteristics of the output current versus the input current of the current amplifier shown in FIG. 4. The input current is presented in a logarithmic scale. All the transistors of the circuit are minimum-sized. The right-most curve is obtained when V_{gc}=0.4 V, and the left-most curve is obtained when V_{gc}=0.15 V. For a given V_{gc}, the input range for amplification is small, however, the gain can be very high, such as 80 dB. When V_{gc} decrements, the current gain in a lower current level increments. The characteristics shown in FIG. 5 are very interesting and significant for signal detection and amplification. By tuning V_{gc} to a desired current range, the circuit can be used as a current amplifier with a good selectivity to this range of current signals. The characteristics of the circuit also show that the current gain decreases with the increase of V_{gc} and v_{d}.

The frequency response of the circuit depends on the level of the input current. As the circuit has a very simple structure and the parasitic capacitances can be minimized, the operation speed can be much higher than many existing current amplifiers for the same current range. The simulation results show that if the current is around 4 nA, the 3-dB frequency is about 300 kHz, and that for an input around 10 nA, the 3-dB frequency is 700 kHz. FIG. 6 illustrates the waveforms of the input current, the common gate voltage and the output current when the frequency is 100 kHz. The current flowing through transistor N₂ is the amplified current. The load of the circuit is a drain-to-gate shorted PMOS transistor of which the gate area is about 2 μm².

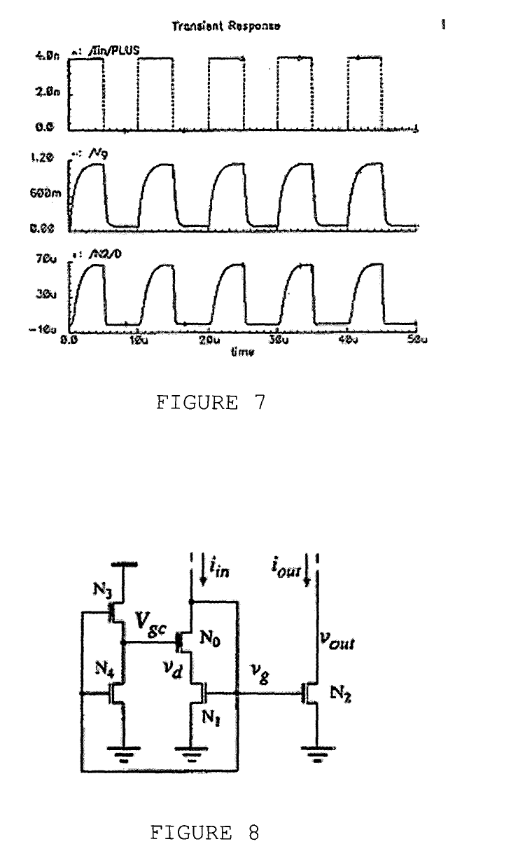

The circuit is capable of detecting binary current signals by selectively amplifying the current representing the high level. This selection can be done by adjusting V_{gc}. The waveforms shown in FIG. 7 are obtained with a current pulse signal as the input signal. The load of the circuit is a drain-gate shorted PMOS transistor of which the gate area is about 2 μm².

The circuit shown in FIG. 4 is extremely efficient in terms of power dissipation. It has only two branches in which the currents are the input and the output, respectively. There is basically no power dissipated in the circuit except that brought by these two currents. It has a relatively narrow input current range and thus has a good selectivity for amplifying only the signals in a desired range. However, it is needed, in many cases, for a current amplifier to have a wide dynamic range. To do so, the voltage v_{d} of the circuit needs to be adjusted with the variation of the input current.

In many detection cases, it is desirable to have a current gain adapting automatically to the signal magnitude, higher gain for the signal of small magnitude and lower one for that of large magnitude, thereby resulting in an adaptive gain profile. In this manner, the circuit will be able to catch the signal variation over a wide range. One of the approaches to this adaptation is to make V_{gc} decrease or increase with the input current so that if the current decrease (or increases), the gain will increase (or decrease).

The circuit shown in FIG. 8 is a preferred embodiment for the high gain adaptive current amplifier according to the present invention. A feedback block, consisting of transistors N₃ and N₄ is added to the basic structure shown in FIG. 4. If the input current gets weakened, v_{g} will decrease and make, by means of N₃ and N₄, V_{gc} and v_{d} vary in the same direction, which results in an increase of v_{g}. Thus the gain of the circuit will be increased for the weakened input current. The transistors N₃ and N₄ make a voltage divider of which the division ratio V_{gc}/V_{DD} is controlled by v_{g}. The feedback ratio ΔV_{gc}/Δv_{g} is determined by the aspect ratios of the transistors N₃ and N₄. It should be noted that, the feedback block of N₃ and N₄ can be replaced by another device, provided that 0<V_{gc}/v_{g}<1.

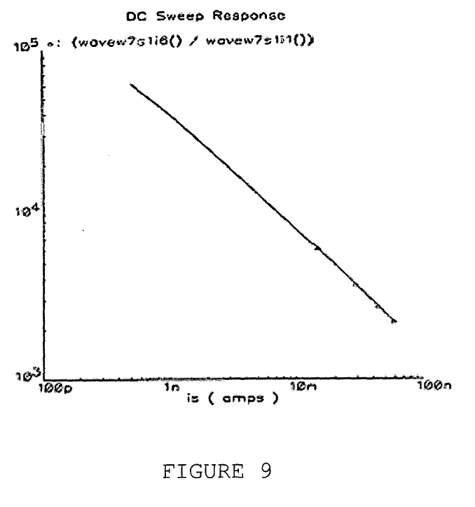

The simulation results of the circuit of FIG. 8 are shown in FIG. 9, where the current gain versus the input current of the current amplifier in FIG. 8 is illustrated. All the transistors are minimum-sized except N₄ with (W/L)₄=2. The signal and the gain are both presented in logarithmic scale. The gain is 50K for iᵢₙ=0.5 nA and 1K for iᵢₙ=60 nA. The results are obtained with specified aspect ratios of the transistors in the feedback block. The gain, in the case of the weakest input current, is 50 times stronger than that in the case of the strongest current. The weakest input current was 0.5 nA for the simulation, but it should be much lower in real applications.

The potential applications of the circuits illustrated include current detection and amplifications in signal acquisitions, signal processing, remote control, VLSI circuit fault detection and communication systems. In particular, this design scheme is very useful for developing current-based sensors, such as optical sensors. The advantages of the circuits, such as high gain to weak current, low power dissipation, and simple structure, will enable significant improvements in signal ranges, power supplies, and other aspects of the systems, which can also lead to new applications of the systems.

It will be understood that numerous modifications thereto will appear to those skilled in the art. Accordingly, the above description and accompanying drawings should be taken as illustrative of the invention and not in a limiting sense. It will further be understood that it is intended to cover any variations, uses, or adaptations of the invention following, in general, the principles of the invention and including such departures from the present disclosure as come within known or customary practice within the art to which the invention pertains and as may be applied to the essential features herein before set forth, and as follows in the scope of the appended claims.

1. A method for amplifying an input current signal to provide an output current signal according to a predetermined gain profile, the method comprising:
providing a first and a second semiconductor device each having at least a control terminal and two current terminals for a current to flow therethrough, wherein said input current signal is fed through said current terminals of said first semiconductor device and said output current signal passes through said current terminals of said second semiconductor device;
controlling a second voltage level of said control terminal of said second semiconductor device such that said second voltage level follows a first voltage level of a control terminal of said first semiconductor device;
providing circuitry responsive to said input current signal to provide said first voltage level such that said first voltage level varies with said input current signal to cause said second semiconductor device to generate said output current signal according to said predetermined gain profile, wherein said circuitry biases said first semiconductor device in a first operating region, and wherein said second semiconductor device is biased in a second operating region having a higher device-current to control-voltage ratio than said first operating region.

2. A method as claimed in claim 1, wherein said circuitry biases said first semiconductor device in a triode region.

3. A method as claimed in claim 2, wherein said circuitry biases said second semiconductor device in a saturation region.

4. A method as claimed in claim 1, wherein said providing circuitry comprises providing a third semiconductor device having at least a control terminal and two current terminals for a current to flow therethrough, said third semiconductor device connected to said first semiconductor device in such a way that said control terminal of said third semiconductor device can adjust a voltage across said current terminals of. said first semiconductor device, while a signal at said control terminal of said first semiconductor device still varies according to said input current signal.

5. A method as claimed in claim 1, wherein said predetermined gain profile is adaptive, and said providing circuitry comprises providing a feedback system which causes a voltage across said current terminals of said first semiconductor device to vary as a function of said input current signal such that a decrease of said input current signal will produce a sufficient change in said voltage across said current terminals to result in an increase in current gain.

6. A method as claimed in claim 5, wherein said providing circuitry comprises providing a third semiconductor device having at least a control terminal and two current terminals for a current to flow therethrough, said third semiconductor device connected to said first semiconductor device in such a way that said control terminal of said third semiconductor device can adjust said voltage across said current terminals of said first device, while a signal at said control terminal of said first semiconductor device still varies according to said input current signal.

7. A method as claimed in claim 6, wherein said providing a feedback system comprises feeding back said first voltage level of said first semiconductor device to said control terminal of said third semiconductor device such that a decrease in said first voltage level will result in a lower voltage at said control terminal of said third semiconductor device.

8. A method as claimed in claim 7, wherein said feeding back said first voltage level comprises feeding back via a voltage divider, wherein a division ratio is controlled by said first voltage level.

9. A method as claimed in claim 8, wherein said voltage divider comprises a pair of semiconductor devices cascoded together between an upper supply voltage and a lower supply voltage.

10. A circuit for amplifying an input current signal to provide an output current signal according to a predetermined gain profile, the circuit comprising:
a first semiconductor device having at least a control terminal and two current terminals for a current to flow therethrough, wherein said input current signal passes through said current terminals of said first semiconductor device;
a second semiconductor device having at least a control terminal and two current terminals for a current to flow therethrough, wherein a second voltage level of said control terminal of said second semiconductor device follows a first voltage level of said control terminal of said first semiconductor device, and wherein said output current signal passes through said current terminals of said second semiconductor device; and
circuitry responsive to said input current signal to provide said first voltage level such that said first voltage level varies with said input current signal to cause said second semiconductor device to generate said output current signal according to said predetermined gain profile, wherein said circuitry biases said first semiconductor device in a first operating region, and wherein said second semiconductor device is biased in a second operating region having a higher device-current to control-voltage ratio than said first operating region.

11. A circuit as claimed in claim 10, wherein said first semiconductor device is biased in a triode region by said circuitry.

12. A circuit as claimed in claim 11, wherein said second semiconductor device is biased in a saturation region by said circuitry.

13. A circuit as claimed in claim 10, wherein said circuitry comprises a third semiconductor device having at least a control terminal and two current terminals for a current to flow therethrough, in series with said first semiconductor device such that said input current signal is fed through said current terminals of said third semiconductor device, and wherein said input current terminal of said third semiconductor device is connected to said control terminal of said first semiconductor device, whereby applying a control signal to said control terminal of said third semiconductor device sets a voltage across said first semiconductor device.

14. A circuit as claimed in claim 10, wherein said first semiconductor device and said second semiconductor device are metal-oxide field effect transistors.

15. A circuit as claimed in claim 14, wherein said first semiconductor device and said second semiconductor device have substantially identical size aspect ratios.

16. A circuit as claimed in claim 10, wherein said predetermined gain profile is adaptive, and said circuitry comprises a feedback system which causes a voltage across said current terminals of said first semiconductor device to vary as a function of said input current signal such that a decrease of said input current signal will produce a sufficient change in said voltage across said current terminals of said first semiconductor device to result in an increase in current gain.

17. A circuit as claimed in claim 16, wherein said circuitry comprises a third semiconductor device having at least a control terminal and two current terminals for a current to flow therethrough, in series with said first semiconductor device such that said input current signal is fed through said current terminals of said third semiconductor device, and wherein one of said current terminals of said third semiconductor device is connected to said control terminal of said first semiconductor device, whereby applying a control signal to said control terminal of said third semiconductor device sets said voltage across said first semiconductor device.

18. A circuit as claimed in claim 17, wherein said feedback system comprises a voltage divider between said control terminal of said first semiconductor device and said control terminal of said third semiconductor device, wherein a division ratio is controlled by said first voltage level.

19. A circuit as claimed in claim 18, wherein said voltage divider comprises a pair of semiconductor devices cascoded together between an upper supply voltage and a lower supply voltage.
